(19) United States
(12) Patent Application Publication
(10) Pub. No.: US 2020/0392619 A1
(43) Pub. Date: Dec. 17, 2020

(54) APPARATUS AND METHOD OF PROCESSING A SUBSTRATE

(71) Applicants: SK hynix Inc., Icheon-si Gyeonggi-do (KR); EUGENE TECHNOLOGY CO., LTD., Yongin-si Gyeonggi-do (KR)

(72) Inventors: Min Jin JUNG, Hwaseong-si Gyeonggi-do (KR); Tae Hwan KIM, Yongin-si Gyeonggi-do (KR); Min Woong KANG, Hwaseong-si Gyeonggi-do (KR); Hyun Jun YOO, Seoul (KR); Sung Ho KANG, Yongin-si Gyeonggi-do (KR); Song Hwan PARK, Yongin-si Gyeonggi-do (KR); Bo Sun KIM, Yongin-si Gyeonggi-do (KR); Hong Won LEE, Yongin-si Gyeonggi-do (KR); Joo Hyun CHO, Yongin-si Gyeonggi-do (KR); Yong Tak JIN, Yongin-si Gyeonggi-do (KR)

(73) Assignees: SK hynix Inc., Icheon-si Gyeonggi-do (KR); EUGENE TECHNOLOGY CO., LTD., Yongin-si Gyeonggi-do (KR)

(21) Appl. No.: 16/700,921

(22) Filed: Dec. 2, 2019

(30) Foreign Application Priority Data
Jun. 17, 2019 (KR) 10-2019-0071561

(51) Int. Cl. C23C 16/44; C23C 16/458; C23C 16/46

(52) U.S. Cl. CPC C23C 16/4411; C23C 16/46; C23C 16/4412; C23C 16/4583

(57) ABSTRACT

An apparatus for processing a substrate includes a reaction tube, a side cover, a heater, a first gas supplier, a second gas supplier and a controller. The reaction tube is configured to receive a substrate boat in which a plurality of the substrate is received to process the substrate. The side cover is configured to receive the reaction tube. The heater lines the interior of the side cover. The first gas supplier is provided to an upper portion of the side cover to supply a cooling gas at a first supplying rate to a space between the side cover and the reaction tube. The second gas supplier is provided to a lower portion of the side cover to supply the cooling gas at a second supplying rate different from the first supplying rate to the space between the side cover and the reaction tube. The controller controls the reaction tube.

### CROSS-REFERENCES TO RELATED APPLICATION

The present application claims priority under 35 U.S.C. § 119(a) to Korean application number 10-2019-0071561, filed on Jun. 17, 2019, in the Korean Intellectual Property Office, which is incorporated herein by reference in its entirety.

### BACKGROUND

### 1. Technical Field

Various embodiments may generally relate to an apparatus and a method of processing a substrate, more particularly, to an apparatus and a method of processing a substrate that may be capable of controlling a cooling speed and temperature uniformity in a reaction tube.

### 2. Related Art

Semiconductor fabrication processes may include a process of processing a substrate to form a layer on the substrate through a chemical vapor deposition (CVD) process. The substrate processing process may include loading a substrate boat with a plurality of the substrates into a reaction tube, and supplying a reaction gas into the reaction tube in a vacuum.

The temperature of the substrate may increase during the substrate processing process. Thus, after the substrate processing process, it may be required to cool the substrate boat in order to transfer the substrate. An atmospheric pressure may be applied to the reaction tube. External air or nitrogen gas may also be supplied to the reaction tube to cool the reaction tube. An unloading temperature of the substrate boat may be controlled. The substrate boat may then be unloaded from the reaction tube.

When the reaction tube is naturally cooled, a cooling time may be so long so that the productivity level may decline. In contrast, when the reaction tube is rapidly cooled, a crack may be generated at byproducts on an inner wall of the reaction tube, generated in the substrate processing process. Particles may be generated from the crack of the byproducts.

Therefore, a technology for cooling the reaction tube, while preventing productivity loss from natural cooling and minimizing stresses applied to the byproducts caused by a forced cooling, is being pursued.

### SUMMARY

In example embodiments of the present disclosure, an apparatus for processing a substrate may include a reaction tube, a side cover, a heater, a first gas supplier, a second gas supplier and a controller. The reaction tube may be configured to receive a substrate boat in which a plurality of the substrate may be received to process the substrate. The heater may line the interior of the side cover. The side cover may be configured to receive the reaction tube. The first gas supplier may be provided to an upper portion of the side cover to supply a cooling gas at a first supplying rate to a space between the side cover and the reaction tube. The second gas supplier may be provided to a lower portion of the side cover to supply the cooling gas at a second supplying rate different from the first supplying rate to the space between the side cover and the reaction tube. The controller may control the reaction tube.

In example embodiments of the present disclosure, based on a method of processing a substrate, substrates in a substrate boat may be processed in a reaction tube. A cooling gas may be supplied to a space between the reaction tube and a side cover, which may be configured to receive the reaction tube, to cool the reaction tube to no more than a predetermined temperature. The substrate boat may then be unloaded from the reaction tube. In example embodiments, the cooling of the reaction tube may include supplying the cooling gas at a first supplying rate to an upper region of the space, supplying the cooling gas at a second supplying rate, different from the first supplying rate to a lower region of the space. The cooling gas may then be exhausted from the space.

### BRIEF DESCRIPTION OF THE DRAWINGS

The above and another aspect, features and advantages of the subject matter of the present disclosure will be more clearly understood from the following detailed description taken in conjunction with the accompanying drawings, in which:

FIGS. 1A to 1C are exploded perspective views, illustrating an apparatus for processing a substrate, in accordance with example embodiments;

FIG. 2 is a longitudinal cross-sectional view, illustrating an apparatus for processing a substrate, in accordance with example embodiments;

FIG. 3A to 3C are lateral cross-sectional views, illustrating an apparatus for processing a substrate, in accordance with example embodiments;

FIG. 4A is a flow chart, illustrating a method of processing a substrate, in accordance with example embodiments;

FIGS. 4B to 4D are flow charts, illustrating a process for cooling a reaction tube, in accordance with example embodiments;

FIG. 5 is a block diagram, illustrating a controller, in accordance with example embodiments; and

FIG. 6 is a cross-sectional view, illustrating an apparatus for processing a substrate, in accordance with example embodiments.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

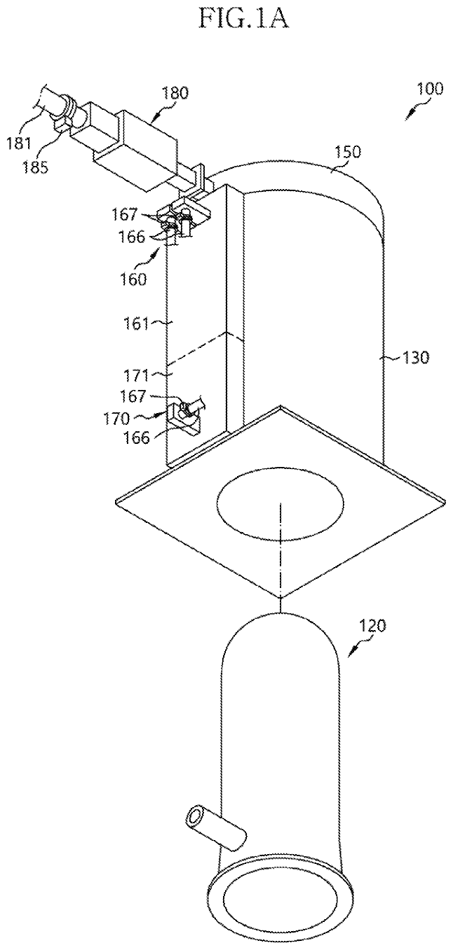

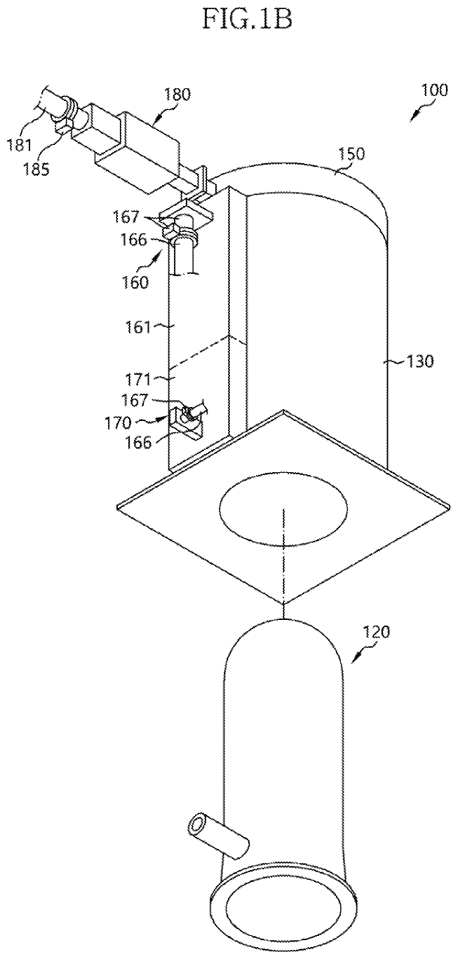

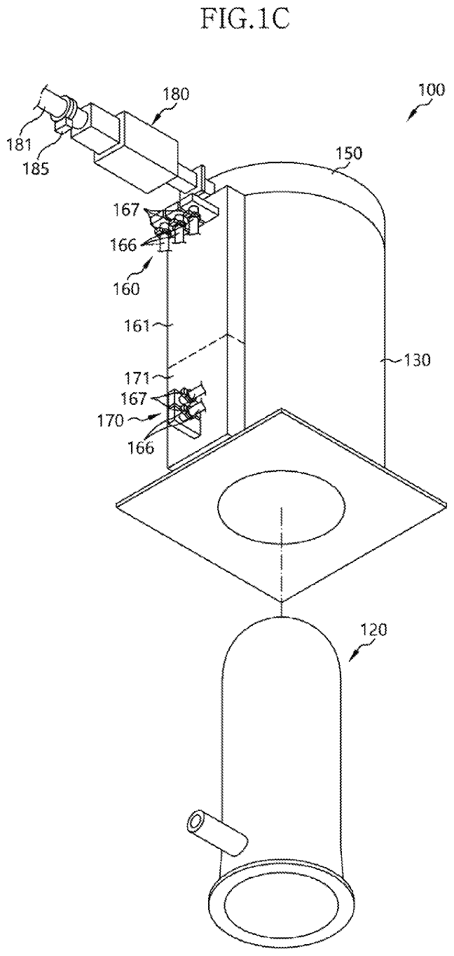

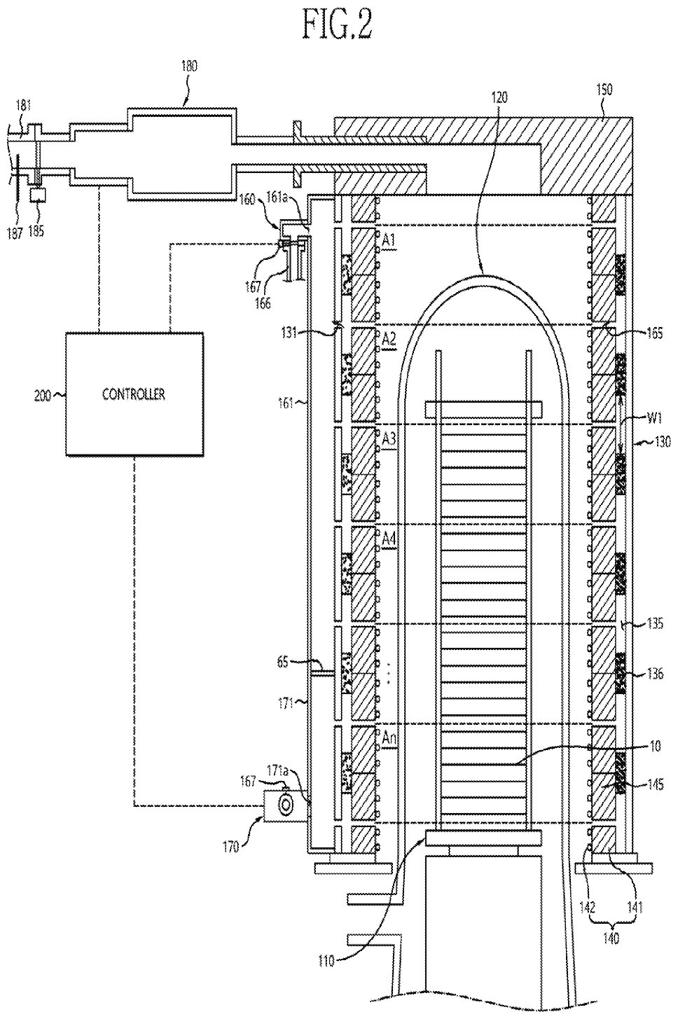

FIGS. 1A to 1C are exploded perspective views, illustrating an apparatus for processing a substrate, in accordance with example embodiments, and FIG. 2 is a longitudinal cross-sectional view, illustrating an apparatus for processing a substrate, in accordance with example embodiments.

Referring to FIGS. 1A and 2, an apparatus 100, for processing a substrate, in accordance with example embodiments, may include a substrate boat 110, a reaction tube 120, a side cover 130, a heater 140, a lid 150, a first gas supplier 160, a second gas supplier 170 and a radiant exhauster 180.

In order to perform a substrate-processing process in a batch type, the substrate boat 110 may be configured to receive a plurality of stacked substrates 10. The substrate boat 110 may be received in an internal space of the reaction tube 120 during the substrate-processing process. The substrate boat 110 may have a plurality of processing spaces in which the substrates 10 may be individually processed.

The reaction tube 120 may have the internal space, configured to receive the substrate boat 110 during the substrate-processing process. The substrate-processing process may be performed on the substrates 10 in the substrate boat 110. The reaction tube 120 may include a single tube or a plurality of tubes. For example, the reaction tube 120 may include an outer tube and an inner tube.

The side cover 130 may have an internal space configured to receive the reaction tube 120. The side cover 130 may have a cylindrical shape having an opened upper surface and an opened lower surface. The side cover 130 may include a metal, such as a stainless metal.

The heater 140 may be arranged in the side cover 130, surrounding the reaction tube 120 at a distance, to provide the reaction tube 120 with heat. The heater 140 may be arranged between the reaction tube 120 and the side cover 130. For example, the heater 140 may include a cylindrical adiabatic member 141 and a heating element 142 on an inner surface of the adiabatic member 141. The adiabatic member 141 may include silica and alumina as the main ingredients. The adiabatic member 141 may have a thickness of about 30 mm to about 40 mm. The heating element 142 may be arranged on the inner surface of the adiabatic member 141 in a linear shape such as a spiral shape, an oblique shape, etc. The heater 140 may be configured to independently control temperatures of the plurality of vertically arranged regions. The adiabatic member 141 may include an adiabatic block, having a plurality of divided regions, considered a construction ability of the heating element 142. Additionally, a maintenance member (not shown) may be interposed between the adiabatic member 141 and the heating element 142.

The lid 150 may be arranged on the upper end of the side cover 130. The lid 150 may be configured to seal the opened upper surface of the side cover 130. The lid 150 may include a ceiling plate. The ceiling plate may include a metal, such as a stainless metal.

The first gas supplier 160 may be connected to an upper portion of the side cover 130 to supply a cooling gas, such as external air, nitrogen gas, etc., into a space between the side cover 130 and the reaction tube 120. The first gas supplier 160 may supply the cooling gas, at a first supplying rate, to the space. Particularly, the first gas supplier 160 may supply the cooling gas to the upper region of the space between the side cover 130 and the reaction tube 120. More particularly, the first gas supplier 160 may also supply the reaction gas to an upper region in the reaction tube 120.

The second gas supplier 170 may be connected to a lower portion of the side cover 130. The second gas supplier 170 may supply the cooling gas into the space between the space between the side cover 130 and the reaction tube 120. The second gas supplier 170 may supply the cooling gas at a second supplying rate, different from the first supplying rate, to the space. Particularly, the second gas supplier 170 may supply the second gas to the lower region of the space, between the side cover 130 and the reaction tube 120.

The radiant exhauster 180 may be connected with the lid 150 to exhaust the cooling gas in the side cover 130. Hot air may be positioned in the upper region of the internal space in the reaction tube 120 or the side cover due to convection. Thus, the radiant exhauster 180 may absorb heat from the reaction tube 120 to effectively discharge the heat using the upward-moving air.

The upward movement of the hot air and a downward movement of a cold air by convection, and the position of the radiant exhauster 180, over the reaction tube 120, may cause a non-uniform cooling rate of the apparatus 100, particularly, the reaction tube 120.

In example embodiments, in order to compensate for the difference in the cooling rates in the apparatus 100, the amount of cooling gas, supplied by the first gas supplier 160, may be different from the amount of the cooling gas, supplied by the second gas supplier 170.

For example, the first gas supplier 160, which may be positioned at the upper region of the apparatus 100, having a relatively high temperature, may supply a first amount of the cooling gas to the apparatus 100. In contrast, the second gas supplier 170, which may be positioned at the lower region of the apparatus 100, having a relatively low temperature, may supply a second amount of the cooling gas that is less than the first amount to the apparatus 100. Thus, the temperature deviation of the vertically extended apparatus 100, i.e., the reaction tube 120, may be reduced.

As mentioned above, the amount of cooling gas, supplied by the first gas supplier 160, may be greater than the amount of the cooling gas, supplied by the second gas supplier 170. Because the hot air may be located in the upper region of the reaction tube 120 and the radiant exhauster 180 may be positioned at the upper region of the reaction tube 120, the hot air may stay for a longer time in the upper region of the reaction tube 120 compared to the hot air in the rest of the reaction tube 120. Thus, the cooling speed of the upper region in the reaction tube 120 may be slower than the cooling speed of the lower region in the reaction tube 120.

In contrast, because the cold air may stay in the lower region of the reaction tube 120, the lower region of the reaction tube 120 may be cooled relatively quickly. Thus, when the supplying amount of the cooling gas, by the first gas supplier 160, is substantially the same as or lower than that of the second gas supplier 170, the lower region of the reaction tube 120 may be cooled relatively faster, generating a temperature difference between the upper region and the lower region in the reaction tube 120. In this case, the substrates 10 may have different temperatures, in accordance with positions of the substrates 10 in the reaction tube 120, so that layers on the substrates 10 may have different characteristics. As a result, a uniform layer might not be formed on the substrates 10.

In example embodiments, because the supplying amount of the cooling gas by the first gas supplier 160, positioned at the upper region of the reaction tube 120, may be greater than that of the second gas supplier 170, positioned at the lower region of the reaction tube 120, the cooling rate (cooling speed) of the upper region in the reaction tube 120 may be improved to decrease the difference between the cooling speed in the upper region and the lower region of the reaction tube 120. Further, the temperature deviation between the upper region and the lower region in the reaction tube 120, which may be caused by a faster cooling of the lower region of the reaction tube 120, may be prevented. Therefore, the substrate-processing process may be performed on the substrates 10 in the reaction tube 120 to obtain the uniform layer from the substrates 10.

The first gas supplier 160 and the second gas supplier 170 may include gas supply pipes 166, through which the cooling gas may flow. The radiant exhauster 180 may include an exhaust pipe 181, through which the cooling gas may be exhausted. The exhaust pipe 181 may have a diameter (a width) greater than that of the gas supply pipe 166.

The cooling gas may be supplied into the side cover 130 through the gas supply pipes 166 of the first and second gas supplier 160 and 170. For example, a diameter of the gas supply pipe 166 of the first gas supplier 160 may be substantially the same as the diameter of the gas supply pipe 166 of the second gas supplier 170. In contrast, as shown in FIG. 1B, the diameter of the gas supply pipe 166 of the first gas supplier 160 may be greater than the diameter of the gas supply pipe 166 of the second gas supplier 170.

Each of the first and second gas suppliers 160 and 170 may include a plurality of the gas supply pipes 166. As shown in FIG. 1C, numbers of the gas supply pipes 166 in the first gas supplier 160 may be greater than the number of gas supply pipes 166 in the second gas supplier 170.

As mentioned above, the radiant exhauster 180 may include the exhaust pipe 181 to exhaust the cooling gas. An exhausting amount or an exhausting speed of the cooling gas may be determined, in accordance with an exhaust pressure, by the diameter of the exhaust pipe 181 and a blower (not shown).

In example embodiments, the width of the exhaust pipe 181 may be greater than the width of the gas supply pipe 166. The first and second gas suppliers 160 and 170 may supply the cooling gas, using the at least two gas supply pipes 166. In order to readily exhaust the cooling gas from the side cover 130, the exhaust pipe 181 may have the width greater than that of the gas supply pipe 166 to increase the exhausting amount of the cooling gas. Thus, the cooling gas in the side cover 130, which may be supplied through the gas supply pipes 166, may be effectively exhausted. As a result, the cooling gas in the side cover 130 may be effectively exhausted regardless of the supplying amount of the cooling gas by the first gas supplier 160 and/or the second gas supplier 170.

The apparatus 100 may further include a controller 200 configured to control the cooling rate of the reaction tube 120. FIG. 5 is a block diagram illustrating a controller in accordance with example embodiments.

Referring to FIG. 5, the controller 200 may control the cooling rate of the reaction tube 120. For example, the controller 200 may individually control the cooling rates of the vertically arranged regions in the reaction tube 120. The controller 200 may include a heater control member 210, a cooling gas control member 220 and an exhaust control member 230. Operations of the heater control member 210, the cooling gas control member 220 and the exhaust control member 230 may be illustrated later.

The internal space of the reaction tube 120 may be vertically divided into the regions A1˜An. The heater 140 may be divided into a plurality of heating members 145. The heating members 145 may correspond to the regions A1˜An in one by one relation. Thus, one heating member 145 may heat one region. The heating members 145 may be individually controlled by the heat control member 210. Each of the heating members 145 may include the adiabatic member 141 and the heating element 142. In order to separately control the regions A1˜An, the adiabatic members 141 and the heating elements 142 may be classified by the regions A1˜An. That is, the heating members 145 may be individually arranged by the regions A1˜An.

The heater control member 210 may drive the heating member 145 in the region having a relatively low temperature in accordance with a temperature distribution of the regions A1˜An to compensate for the low temperature of the region. As a result, the temperature uniformity in the reaction tube 120 may be maintained.

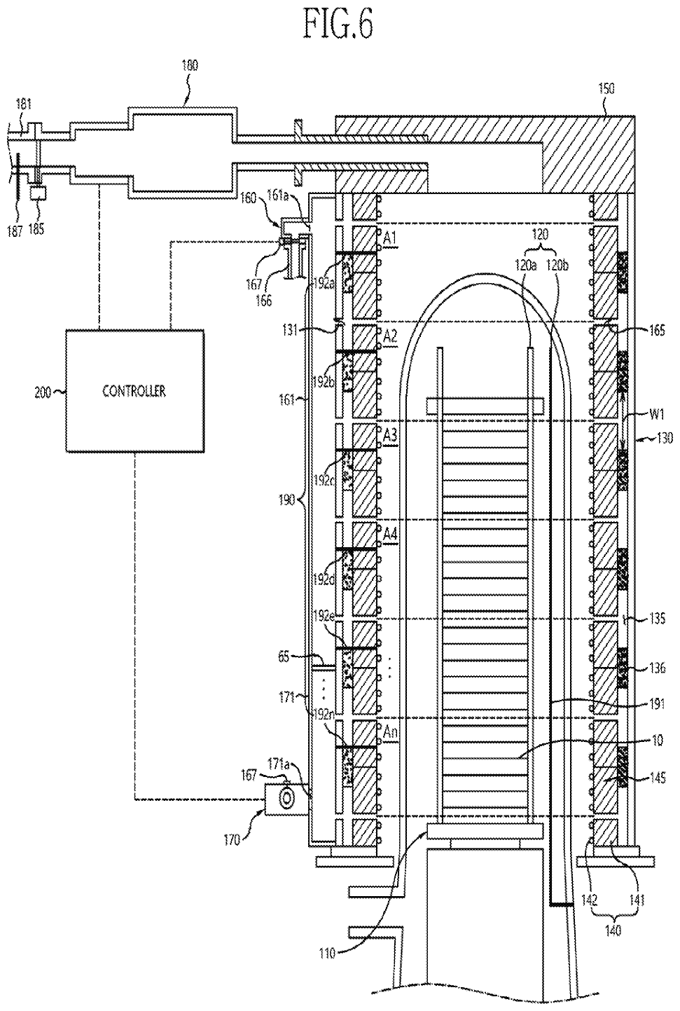

FIG. 6 is a cross-sectional view, illustrating an apparatus for processing a substrate, in accordance with example embodiments.

Referring to FIG. 6, the apparatus 100, for processing the substrate, may further include a temperature sensor 190.

The temperature sensor 190 may measure temperatures of the regions A1˜An in the reaction tube 120. The measured temperatures, by the temperature sensor 190, may be provided to the controller 200. The controller 200 may recognize the temperature distribution based on the regions A1˜An.

The temperature sensor 190 may include a first temperature detection member 191 and a second temperature detection member 192.

The first temperature detection member 191 may be arranged in the reaction tube 120 to measure the temperatures of the regions A1˜An. The first temperature detection member 191, in the reaction tube 120, may measure the temperature in the reaction tube 120 in a vacuum state to identify whether the reaction tube 120 can be normally cooled or not. The first temperature detection member 191 may be positioned adjacent to the substrate 10 in the reaction tube 120 to measure the temperature in the reaction tube 120. The measured temperature, by the first temperature detection member 191, may correspond to a peripheral temperature of the substrate 10. Thus, a temperature of the substrate 10 may be estimated from the peripheral temperature of the substrate 10.

The first temperature detection member 191 may include a profile thermocouple. The profile thermocouple may be installed between the inner tube 120a and the outer tube 120b of the reaction tube 120. Alternatively, the first temperature detection member 191 may be arranged in the reaction tube 120, for example, the inner tube 120a to measure an actual temperature in the reaction tube 120.

The second temperature detection member 192a-192n may be arranged between the reaction tube 120 and the heater 140. The second temperature detection member 192a-192n may measure the temperatures of the regions A1˜An. For example, second temperature detection member 192a-192n may be connected to the heater 140 to measure a temperature of each of the heating members 145. The second temperature detection member 192a-192n may include a spike thermocouple. The second temperature detection member 192a-192n may be in direct contact with the heater 140 or may be arranged between the heater 140 and the reaction tube 120 to measure the temperature or the atmospheric temperature outside of the reaction tube 120, surrounding the heater 140.

The temperatures between the heater 140 and the reaction tube 120, measured by the second temperature detection member 192a-192n, may be provided to the controller 200. The controller 200 may identify whether the regions A1˜An can be normally cooled or not, based on the provided temperatures.

For example, when a specific region of the regions A1˜An might not be uniformly cooled, the controller 200 may decrease a heating temperature of the heating member 145 in the specific region, having a relatively high temperature. In contrast, when a specific region of the regions A1˜An is relatively cooled rapidly, the controller 200 may increase a heating temperature of the heating member 145, in the specific region, having a relatively low temperature.

The temperature controls of the heating members 145 may be performed by the heater control member 210 of the controller 200. The heater control member 210 may control the heating members 145 to supply thermal energy to a region among the regions A1˜An having a relatively low temperature, based on the temperatures of the regions A1˜An measured by the temperature detection members 191 and 192a-192n. As mentioned above, because the hot air may be positioned in the upper region of the reaction tube 120 and the cold air may be positioned in the lower region of the reaction tube 120 due to convection, the temperature deviation between the upper region and the lower region in the reaction tube 120 may be generated.

In order to reduce the temperature deviation, the heater control member 210 may independently control the heating members 145 in a region among the regions A1˜An, having a non-uniform temperature distribution, based on the temperatures of the regions A1˜An, measured by the temperature detection members 191 and 192a-192n.

A plurality of gas supply holes 165 may be arranged in the side cover 130. For example, the gas supply holes 165 may be positioned between the heating members 145.

The first gas supplier 160 may be positioned at an upper portion of the side cover 130. The first gas supplier 160 may include a first duct 161, connected to the gas supply holes 165, located outside the upper region of the reaction tube 120.

The second gas supplier 170 may be positioned at a lower portion of the side cover 130. The second gas supplier 170 may include a second duct 171, connected to the gas supply holes 165 located, outside the lower region of the reaction tube 120.

The first duct 161 and the second duct 171 may supply and distribute the cooling gas. For example, the first duct 161 may extend in a downward direction from an outer surface of the upper portion of the side cover 130. The second duct 171 may be upwardly extended from an outer surface of the lower region of the side cover 130. The first duct 161 may be connected to the second duct 171. An external cooling space may be formed between the first gas supplier 160, the second gas supplier 170, the first duct 161, the second duct 171 and the side surface of the side cover 130.

The gas supply holes 165 may be provided to the regions A1˜An, respectively. That is, the gas supply holes 165 may be positioned in each of the regions A1˜An.

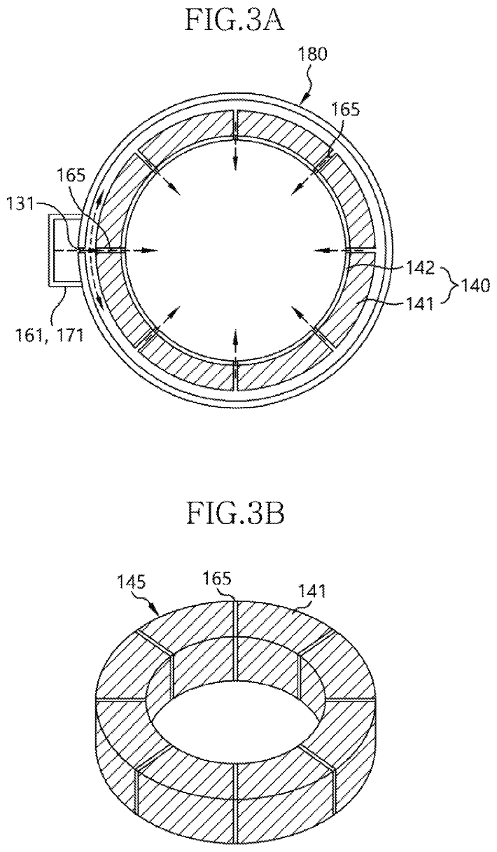

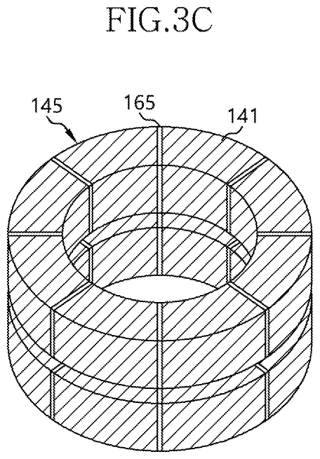

FIG. 3A is a lateral cross-sectional view, illustrating an apparatus for processing a substrate, in accordance with example embodiments, and FIGS. 3B and 3C are perspective views illustrating a heating member in accordance with example embodiments.

Referring to FIGS. 2, 3A and 3B, the heater 140 may be configured to surround the outer surface of the reaction tube 120. The heater 140 may be divided by the regions of the reaction tube 120 to form the heating members 145. Each of the heating members 145 may include the annular adiabatic member 141. The gas supply holes 165 may be arranged in the heating member 145. The gas supply holes 165 may be arranged, spaced apart from each other, along a circumferential direction of the reaction tube 120. For example, the four to fifteen gas supply holes 165 may be provided to one heating member 145. An inner passageway 135 may be formed at an outer circumferential surface of the heating member 145. The inner passageway 135 will be illustrated later. The gas supply holes 165 may be connected to the inner passageway 135.

Referring to FIG. 3C, the heating member 145 may include the single adiabatic member 141 or the stacked adiabatic members 141. The gas supply hole 165 may be provided to each of the adiabatic members 141. The heating member 145 may include the vertically arranged gas supply holes 165.

In example embodiments, in order to provide the cooling gas with a spiral flow along a peripheral direction of the space, between the side cover 130 and the reaction tube 120, the gas supply hole 165 may be inclined to a central direction of the adiabatic member 141 at an angle of about 35° from a planar view.

In example embodiments, before installing the side cover 130, an inner surface or an outer surface of the adiabatic member 141 may be drilled to form the gas supply hole 165.

The inner passageway 135 may have a width w1, greater than a width of the gas supply hole 165. The inner passageway 135 may be connected to the gas supply hole 165. The inner passageway 135 may be connected to the first duct 161 and/or the second duct 171.

The cooling gas provided from the first duct 161 and/or the second duct 171 may be supplied to the inner passageway 135. The cooling gas may then be rapidly diffused along the periphery of the reaction tube 120. The cooling gas may be uniformly distributed in the periphery of the reaction tube 120 through the gas supply holes 165.

For example, a plurality of the inner passageways 135 may be vertically arranged between the adiabatic member 141 of the heater 140 and the side cover 130.

When the cooling gas is injected, from the annular inner passageway 135, toward the central direction of the adiabatic member 141, the cooling gas may be injected to the space between the side cover 130 and the reaction tube 120, through the gas supply hole 165 of the adiabatic member 141. During the injection of the cooling gas, the spiral flow may be generated in the space between the side cover 130 and the reaction tube 120 along the peripheral direction. The inner passageway 135 may be formed by attaching a band-shaped or an annular external adiabatic member 136 on an outer surface of the adiabatic member 141, or by forming an annular shape on the outer surface of the adiabatic member 141. The annular inner passageway 135 may be provided to the peripheral of the reaction tube 120 in a tubular shape.

As shown in FIG. 2, the external adiabatic member 136 may be attached to the outer surface of the adiabatic member 141 of the heating member 145. The external adiabatic member 136 may be inserted into the space between the heating member 145 and the side cover 130. For example, the external adiabatic member 136 may be fixed to the adiabatic member 141 using an adhesive. The external adiabatic member 141 may have a thickness of about 15 mm to about 20 mm and a width of about 30 mm to about 50 mm. The inner passageways 135 may be defined by installing the external adiabatic member 136.

A plurality of connection holes 131 may be formed at the side cover 130. The connection holes 131 may be spaced apart from each other by a uniform gap. The connection holes 131 may be positioned in a space, defined by the first duct 161 and the second duct 171. Thus, the external cooling space, the inner passageway 135, and the gas supply holes 165 may be connected with each other through the connection holes 131. Each of the gas supply holes 165 may be connected with either the first gas supplier 160, through the inner passageway 135, the connection hole 131 and the first duct 161, or the second gas supplier 170, through the inner passageway 135, the connection hole 131 and the second duct 171.

A blower may be provided to inlets 161a and 171a of the first and second ducts 161 and 171 through an opening/closing valve 167. The blower may draw the external air as the cooling gas.

For example, the first duct 161 may have a length longer than that of the second duct 171. A partition 65, configured to define the external cooling space, may be arranged at an interface between the first duct 161 and the second duct 171. The first duct 161 may be connected to or may face the gas supply holes 165, relatively more than the second duct 171. The cooling gas, introduced into the external cooling space, may be thermally exchanged with the external air so that the cooling gas may be rapidly heated.

The lower region of the space, between the side cover 130 and the reaction tube 120, where the cold air may be positioned, may have a volume larger than the upper region space between the side cover 130 and the reaction tube 120, where the hot air may be positioned. Thus, a relatively rapid cooling region has a volume of no more than about 50%, for example, about 10% to about 40% of the volume of the space, between the side cover 130 and the reaction tube 120. Therefore, in order to cool the relatively rapid cooling region, it might not be required to connect the second duct 171 of the second gas supplier 170, which may supply the cooling gas having the relatively small amount, with a relatively great amount of the gas supply holes 165. That is, the second duct 171 may be connected to only the gas supply hole 165 provided to the space or the region having the relatively small volume where the cold air may be positioned. In contrast, the first duct 161 of the first gas supplier 160 may be connected to the relatively great amount of the gas supply holes 165 having the relatively large volume where the hot air may be positioned. As a result, the relatively great amount of the cooling gas may be supplied to the upper region where the hot air may be positioned to effectively cool the upper region.

The first duct 161 and the second duct 171 may be integrally formed with each other. Numbers of the gas supply holes 165 connected with the first duct 161 and the second duct 171 may be determined in accordance with positions of the partition 65. For example, when the regions A1˜An or the internal passageway mis divided into seven regions or seven passageways, the first duct 161 may be connected to the five upper passageways 135 and the second duct 171 may be connected to the two lower passageways 135. Alternatively, a space divided by the first duct 161 and the partition 65 may have a volume of about 60% to about 90% of the volume of the total space. A space divided by the second duct 171 and the partition 65 may have a volume of about 10% to about 40% of the volume of the total space.

The apparatus 100 may further include an exhaust measurement member 187. The exhaust measurement member 187 may be connected to the radiant exhauster 180 to measure an exhaust pressure and/or an exhaust speed. The exhaust pressure and/or the exhaust speed measured by the exhaust measurement member 187 may be transmitted to the controller 200.

The exhaust measurement member 187 may measure the exhaust pressure and/or the exhaust speed of the radiant exhauster 180 to obtain exhaust intensity. The exhaust measurement member 187 may measure the exhaust pressure using an output value of a blower in the radiant exhauster 180. The exhaust measurement member 187 may measure the exhaust pressure and/or the exhaust speed using a sensor installed at the exhaust pipe 181 of the radiant exhauster 180.

The controller 200 may determine whether the measurement results of the exhaust control member 230, i.e., the exhaust pressure and/or the exhaust speed of the radiant exhauster 180 may be beyond a predetermined set value or not. When the measurement result is beyond the set value, the exhaust control member 230 may output a control signal to decrease the exhaust pressure and/or the exhaust speed of the radiant exhauster 180 to no more than the set value.

The word “predetermined” as used herein with respect to a parameter, such as a predetermined set value, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

When the exhaust pressure and/or the exhaust speed of the radiant exhauster 180 is beyond the set value, stresses, applied to the byproducts on the inner surface of the reaction tube 120, may be increased to generate a crack in the byproducts. Thus, particles may be generated from the crack in the reaction tube 120. In order to prevent the generation of the particles, the exhaust pressure and/or the exhaust speed of the radiant exhauster 180 may be monitored and controlled through the exhaust measurement member 187 to prevent the crack and the lamination of the byproducts in the reaction tube 120 and to improve the cooling speed compared to the natural cooling speed.

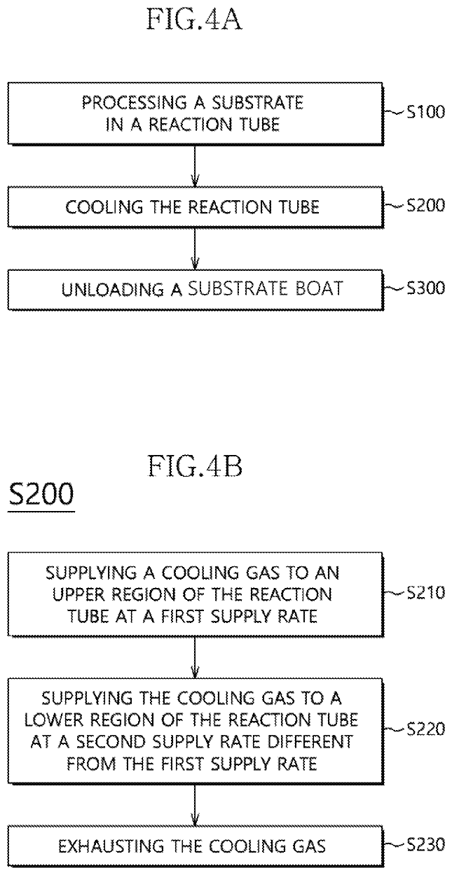

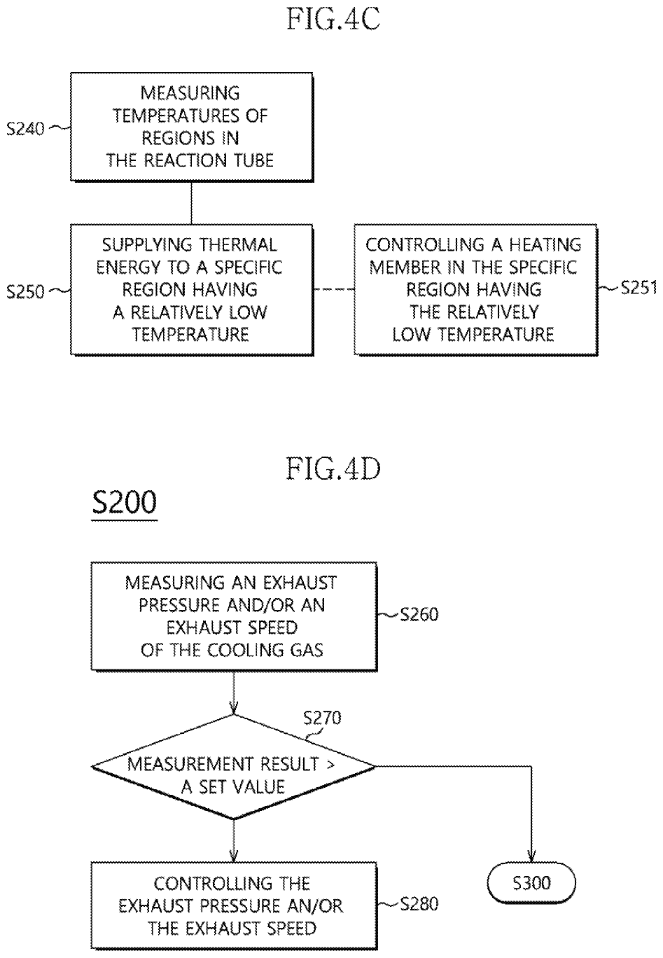

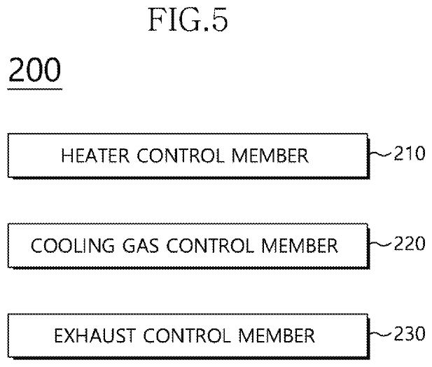

FIG. 4A is a flow chart, illustrating a method of processing a substrate, in accordance with example embodiments.

Referring to FIG. 4A, in step S100, the substrates stacked in the substrate boat may be processed in the reaction tube. In step S200, the cooling gas may be supplied to the space between the side cover and the reaction tube to cool the reaction tube to no more than the predetermined set temperature. In step S300, the substrate boat may be unloaded from the reaction tube having the temperature of no more than the set temperature.

Particularly, in step S100, the substrates in the substrate boat may be processed in the reaction tube. The substrate-processing process may include a deposition process for forming a layer on the substrate. Because the temperature of the substrate may be increased during the deposition process, it may be required to cool the substrate boat in order to transport the substrate after the deposition process.

In step S200, the cooling gas may be supplied to the space between the side cover and the reaction tube to cool the reaction tube to no more than the predetermined set temperature. In order to cool the substrate boat, atmospheric pressure may be applied to the reaction tube. Simultaneously, cooling gas such as external air, nitrogen gas, etc., may be supplied to the space between the side cover and the reaction tube to cool the reaction tube, thereby controlling the unloading temperature of the substrate boat.

In step S300, the substrate boat may be unloaded from the reaction tube having the temperature of no more than the set temperature. When the reaction tube is cooled to no more than the set temperature after controlling the unloading temperature of the substrate boat, the substrate boat may be unloaded from the reaction tube.

FIG. 4B is a flow chart, illustrating a process for cooling a reaction tube, in accordance with example embodiments.

Referring to FIG. 4B, in step S210, the cooling gas may be supplied to the upper region of the space between the side cover and the reaction tube at the first supply rate. In step S220, the cooling gas may be supplied to the lower region of the space at the second supply rate, different from the first supply rate. In step S230, the cooling gas may be exhausted from the space between the side cover and the reaction tube.

Particularly, in step S210, the cooling gas may be supplied to the upper region of the space, between the side cover and the reaction tube, at the first supply rate. The cooling gas may be supplied to the upper region of the space, between the side cover and the reaction tube, through the first gas supplier connected to the upper portion of the side cover. The cooling gas may be supplied to the portion of the upper region in the space between the side cover and the reaction tube.

Particularly, in step S220, the cooling gas may be supplied to the lower region of the space at the second supply rate, different from the first supply rate. The cooling gas may be supplied to the lower region of the space between the side cover and the reaction tube through the second gas supplier connected to the lower portion of the side cover at the second supply rate different from the first supply rate. The cooling gas may be supplied to the rest of the lower region in the space between the side cover and the reaction tube.

Therefore, different amounts of the cooling gas may be supplied to the upper region and the lower region in the reaction tube to maintain the temperature uniformity in the reaction tube during the cooling of the reaction tube. Further, the supplying amounts of the cooling gas to the upper region and the lower region in the reaction tube may be controlled to effectively cool the reaction tube, in accordance with the temperature distribution of the reaction tube. Furthermore, the temperature deviation between the regions in the reaction tube may be decreased during cooling the reaction tube.

Particularly, in step S230, the cooling gas may be exhausted from the space between the side cover and the reaction tube. The cooling gas in the side cover may be exhausted through the radiant exhauster, connected to the lid, on the side cover. Because the hot air may be positioned in the upper region of the reaction tube due to convection, the heat may be effectively exhausted using the upwardly increasing hot air absorbing the heat in the reaction tube.

The amount of the cooling gas supplied to the upper region may be larger than the amount of the cooling gas supplied to the lower region. Because the hot air may stay for a longer time in the upper region compared to the hot air in the lower region due to convection, and the position of the radiant exhauster, configured to exhaust the cooling gas through the upper portion of the side cover, the upper region may be cooled relatively slower than the lower region. In contrast, because the cold air may stay in the lower region, where the hot air may be upwardly moved to the upper region, the lower region may be cooled relatively faster than the upper region. Thus, when the supplying amount of the cooling gas by the first gas supplier is substantially the same as or lower than that by the second gas supplier, the lower region of the reaction tube may be cooled relatively quickly to generate the temperature difference between the upper region and the lower region in the reaction tube. In this case, the substrates may have different temperatures in accordance with the positions of the substrates in the reaction tube so that layers on the substrates may have different characteristics. As a result, a uniform layer might not be formed on the substrates.

In example embodiments, because the supplying amount of the cooling gas by the first gas supplier, positioned at the upper region of the reaction tube, may be greater than that of the second gas supplier positioned at the lower region of the reaction tube, the cooling rate (cooling speed) of the upper region in the reaction tube may be improved to decrease the difference between the cooling speed in the upper region and the lower region of the reaction tube. Further, the temperature deviation between the upper region and the lower region in the reaction tube, which may be caused by cooling the lower region of the reaction tube relatively faster, may be prevented. Therefore, the substrate-processing process may be performed on the substrates in the reaction tube to obtain the uniform layer from the substrates.

FIG. 4C is a flow chart, illustrating a process for cooling a reaction tube, in accordance with example embodiments.

Referring to FIG. 4C, the method of cooling the reaction tube may further include measuring the temperatures of the vertically arranged regions in the reaction tube in step S240 and supplying the thermal energy to the specific region among the regions, having a relatively low temperature, in accordance with the temperatures of the regions in step S250.

Particularly, in step S240, the temperatures of the vertically arranged regions in the reaction tube may be measured. The temperatures of the regions in the reaction tube may be measured using the temperature sensor to obtain the temperature distribution by the regions.

In step S250, the thermal energy may be supplied to the specific region, having the relatively low temperature, among the regions, in accordance with the measured temperatures of the regions. The thermal energy may be supplied to the specific region, having the relatively low temperature, in accordance with the temperatures of the regions, measured by the temperature sensor to reduce the temperature deviation between the regions.

The process for supplying the thermal energy to the specific region, having the relatively low temperature, in step S250, may include driving the heating member, corresponding to the specific region having the relatively low temperature, using the heater, including the heating members, divided by regions in step S251.

In step S251, the heating member, corresponding to the specific region, having the relatively low temperature, may be controlled by using the heater, including the heating members with divided regions. The heating member may be controlled or driven using the heater to supply the thermal energy to the specific region having the relatively low temperature. Because the hot air in the lower region of the reaction tube may be upwardly moved due to convection, and the cold air may be positioned in the lower region, the temperature deviation between the upper region and the lower region in the reaction tube may be generated without the driving of the heater. The heating member, measured by the temperature sensor, may be driven using the heater to independently supply the thermal energy to the specific region, having the relatively low temperature, thereby minimizing the temperature deviation between the regions of the reaction tube.

Cooling the reaction tube, in step S200, may further include measuring the exhaust pressure and/or the exhaust speed of the cooling gas in step S260, determining whether the measured exhaust pressure and/or the measured exhaust speed of the cooling gas may be beyond the set value or not in step S270, and decreasing the exhaust pressure and/or the exhaust speed of the cooling gas to no more than the set value when the measured exhaust pressure and/or the measured exhaust speed is beyond the set value in step S280.

Particularly, in step S260, the exhaust pressure and/or the exhaust speed of the cooling gas may be measured. The exhaust pressure and/or the exhaust speed of the cooling gas may be measured using the exhaust measurement member, connected to the radiant exhauster. Because an exhaust amount may be changed, in accordance with the supply amount of the cooling gas, the exhaust pressure and/or the exhaust speed of the cooling gas may be measured to recognize the exhaust intensity. The exhaust pressure and/or the exhaust speed of the cooling gas may be measured using the output value of the blower in the radiant exhauster. Alternatively, the exhaust pressure and/or the exhaust speed of the cooling gas may be measured by installing the sensor on the exhaust pipe of the radiant exhauster.

In step S270, whether the measured exhaust pressure and/or the measured exhaust speed of the cooling gas may be beyond the set value or not may be determined. Whether the measured exhaust pressure and/or the measured exhaust speed of the cooling gas may be beyond the set value or not may be determined by using the controller to maintain the exhaust pressure and/or the exhaust speed of no more than the set value.

In step S280, the exhaust pressure and/or the exhaust speed of the cooling gas to no more than the set value may be decreased when the measured exhaust pressure and/or the measured exhaust speed is beyond the set value. When the exhaust pressure and/or the exhaust speed of the radiant exhauster is beyond the set value, stresses applied to the byproducts on the inner surface of the reaction tube may be increased to generate a crack in the byproducts. Thus, particles may be generated from the crack in the reaction tube. In order to prevent the generation of the particles, the exhaust pressure and/or the exhaust speed of the radiant exhauster may be monitored and controlled through the exhaust measurement member to prevent the crack and the lamination of the byproducts in the reaction tube and to improve the cooling speed compared to the natural cooling speed.

Based on example embodiments, the supplying amounts of the cooling gas to the upper region and the lower region in the reaction tube may be different from each other in accordance with the temperature distribution of the reaction tube to effectively cool the reaction tube and to reduce the temperature deviation between the regions of the reaction tube. That is, because the hot air may be positioned in the upper region due to convection, the relatively large amount of the cooling air may be supplied to the upper region of the reaction tube to effectively cool the reaction tube. In contrast, the relatively small amount of the cooling air may be supplied to the lower region of the reaction tube to prevent the lower region from being relatively rapidly cooled, thereby reduce the temperature deviation between the upper region and the lower region in the reaction tube. Further, because the hot air in the lower region of the reaction tube may be upwardly moved due to convection and the cold air may be positioned in the lower region, the temperature deviation between the upper region and the lower region in the reaction tube may be generated without the driving of the heater. The heating member corresponding to the specific region having the relatively low temperature in accordance with the temperatures of the regions measured by the temperature sensor may be driven using the heater including the heating members divided the regions to independently supply the thermal energy to the specific region having the relatively low temperature, thereby minimizing the temperature deviation between the regions of the reaction tube. Furthermore, the exhaust pressure and/or the exhaust speed of the cooling gas may be maintained under no more than the set value to prevent the crack and the lamination of the byproducts in the reaction tube and to improve the cooling speed compared to the natural cooling speed.

The above described embodiments of the present invention are intended to illustrate and not to limit the present invention. Various alternatives and equivalents are possible. The invention is not limited by the embodiments described herein. Nor is the invention limited to any specific type of semiconductor device. Another addition, subtractions, or modifications are obvious in view of the present disclosure and are intended to fall within the scope of the appended claims.

What is claimed is:

1. An apparatus for processing a substrate, the apparatus comprising:
a reaction tube configured to receive a substrate boat in which a plurality of the substrates are stacked to process the substrates;
a side cover configured to receive the reaction tube;
a heater lining the interior of the side cover;
a first gas supplier arranged at an upper portion of the side cover to supply a cooling gas to a space between the side cover and the reaction tube at a first supply rate;
a second gas supplier arranged at a lower portion of the side cover to supply the cooling gas to the space at a second supply rate different from the first supply rate; and
a controller configured to the reaction tube.

2. The apparatus of claim 1,
wherein the first gas supplier is arranged at the upper portion of the side cover to supply a cooling gas to the space between an upper portion of the side cover and an upper portion of the reaction tube at the first supply rate; and
the second gas supplier is arranged at the lower portion of the side cover to supply the cooling gas to the space between a lower portion of the side cover and a lower portion of the reaction tube at the second supply rate.

3. The apparatus of claim 1, further comprising:
a lid, arranged on the side cover, to seal an opened upper surface of the side cover; and
a radiant exhauster, connected with the lid, to exhaust the cooling gas in the side cover.

4. The apparatus of claim 1, wherein the first gas supplier supplies a larger amount of the cooling gas compared to the amount of the cooling gas supplied by the second gas supplier.

5. The apparatus of claim 1, wherein an exhaust pipe is connected to an upper portion of the reaction tube, and the exhaust pipe has a diameter greater than gas supply pipes, connected to the first and second gas suppliers.

6. The apparatus of claim 1, wherein the reaction tube is divided into a plurality of vertically arranged regions, and the heater is divided into a plurality of heating members corresponding to the regions.

7. The apparatus of claim 6, further comprising a temperature sensor configured to measure temperatures of the regions.

8. The apparatus of claim 7, wherein the temperature sensor comprises:
a first temperature detection member, arranged in the reaction tube, to measure the temperatures of the regions; and
a second temperature detection member, arranged between the reaction tube and the heater, provided to each of the regions.

9. The apparatus of claim 7, wherein the controller receives measured temperatures from the temperature sensor to independently control the heating members based on the measured temperatures.

10. The apparatus of claim 6, wherein each of the heating members has an annular shape, configured to surround the reaction tube, and a plurality of gas supply holes are arranged between the heating members along a peripheral direction of the heating member and spaced apart from each other by a uniform gap.

11. The apparatus of claim 2, wherein the first gas supplier comprises a first duct, and the first duct is connected to about 60% to about 90% of upper gas supply holes among total gas supply holes of the reaction tube.

12. The apparatus of claim 11, wherein the second gas supplier comprises a second duct, and the second duct is connected to about 10% to about 40% of lower gas supply holes among the total gas supply holes of the reaction tube.

13. The apparatus of claim 1, wherein an external adiabatic member is interposed between the side cover and each heating member in the heater, and an internal passageway, between the heating member and the reaction tube, is divided into a plurality of passageways.

14. The apparatus of claim 13, wherein each of the passageways has a width greater than that of the gas supply hole.

15. The apparatus of claim 1, wherein the controller comprises:
an exhaust measurement member, connected to the radiant exhauster, to measure an exhaust pressure or an exhaust speed of the radiant exhauster; and
an exhaust control member configured to determine whether the exhaust pressure or the exhaust speed of the radiant exhauster, measured by the exhaust measurement member, is beyond a predetermined set value or not to decrease the exhaust pressure or the exhaust speed of the radiant exhauster to no more than the set value when the measured exhaust pressure or the measured exhaust speed of the radiant exhauster is beyond the set value.

16. A method of processing a substrate, the method comprising:
processing a plurality of the substrates, stacked in a substrate boat, in a reaction tube;
supplying a cooling gas to a space, between the reaction tube and a side cover, configured to receive the reaction tube, to cool the reaction tube at a predetermined set temperature; and
unloading the substrate boat from the reaction tube cooled to no more than the set temperature,
wherein the cooling of the reaction tube comprises:
supplying the cooling gas to an upper region in the space at a first supply rate;
supplying the cooling gas to a lower region in the space at a second supply rate, different from the first supply rate; and
exhausting the cooling gas in the space through an upper portion of the side cover.

17. The method of claim 16, wherein the first supply rate is larger than the second supply rate.

18. The method of claim 16, wherein the cooling of the reaction tube further comprises:
measuring vertically arranged regions in the reaction tube; and
supplying a thermal energy to a specific region among the regions having a relatively low temperature based on the measured temperatures of the regions.

19. The method of claim 18, wherein the supplying of the thermal energy to the specific region comprises driving a heating member among a plurality of heating members, which corresponds to the specific region, having the relatively low temperature.

20. The method of claim 16, wherein cooling the reaction tube further comprises:
measuring an exhaust pressure or an exhaust speed of the cooling gas;
determining whether the measured exhaust pressure or the measured exhaust speed of the cooling gas is beyond a predetermined set value or not; and
decreasing the exhaust pressure or the exhaust speed of the cooling gas to no more than the set value when the measured exhaust pressure or the measured exhaust speed of the cooling gas is beyond a predetermined set value.
